(19) United States
(12) Patent Application Publication
(10) Pub. No.: US 2006/0054495 A1
(43) Pub. Date: Mar. 16, 2006

(54) Substrate processing system

(76) Inventors: Hartmut Rohrmann, Schriesheim (DE); Oliver Rattunde, Werdenberg (CH)

Correspondence Address: PEARNE & GORDON LLP, 1801 EAST 9TH STREET, SUITE 1200, CLEVELAND, OH, 44114-3108, US

(21) Appl. No.: 11/222,270

(22) Filed: Sep. 8, 2005

Related U.S. Application Data
(60) Provisional application No. 60/609,207, filed on Sep. 10, 2004.

(51) Int. Cl. C23C 14/00; C23C 14/32

(52) U.S. Cl. 204/192.12; 204/298.02

(57) ABSTRACT

In a substrate processing system for the treatment of substrates in vacuum two linear assemblies of process modules are stacked one above the other and connected by at least one lift module allowing for the transport from the first set to the second set. Along the traveling path through the first and second set of process modules there is arranged a linear synchronous motor. A substrate carrier with rails interacting with rollers mounted in the processing system is being held by the attractive forces of said linear synchronous motor in vertical position.

### FIELD OF THE INVENTION

This invention relates to a system and processes for handling and manufacturing substrates such as disc shaped information carrier, especially magnetic hard discs. More particularly the invention relates to a transport arrangement for substrates in vacuum with the aid of a magnetic holding and driving device.

### BACKGROUND OF THE INVENTION AND RELATED ART

For the treatment of substrates in vacuum, e.g. the coating with a multiplicity of layers it is a well proven principle to transport the substrates through a linear assembly of evacuated process chambers. The term vacuum chamber means at least a section of a vacuum treatment system under reduced pressure compared with atmospheric pressure. The term process chamber or process module means a section of a treatment system intended to change a physical or chemical condition of a substrate, e.g. heating, cooling, cleaning, etching, treating with gases or other substances, coating.

U.S. Pat. No. 5,658,114 shows a vacuum treatment system for e.g. disc shaped substrates wherein, in a stacked relationship, a second level of processing stations is positioned above a first level of processing stations. Work pieces are fed into the row of processing stations on carriers on one level and, at the end of one row, lifted to the other level and then moved through the other row of process stations, thereby allowing a U-shaped path of the carriers through the apparatus. Alternatively to this “vertical U” a horizontal “U” could be realized with two rows of processing stations side by side. Process stations may, amongst others comprise coating stations, heating and/or cooling stations, load and unload locks.

The basic problem for this type of subsequent inline processing is the vacuum compliant transport from chamber to chamber. The substrates are typically held by a carrier. In simple approaches the carriers are placed on a series of mechanically driven rollers. The motor units at atmosphere are connected to the rollers in the vacuum either by vacuum feed throughs or by magnetic coupling. Only the friction between carrier rails and rollers give the accelerating and deaccelerating forces onto the carriers. This results in narrow limits for the maximum acceleration of the carriers and in long transport times. Additionally the friction of the driving rollers generates particles in the vacuum chamber. Therefore the load of the rails onto the rollers, usually given only by gravity, is sometimes enhanced by magnetic forces. This shifts the friction problems, the acceleration limit and the particle generation to a higher level. U.S. Pat. No. 6,919,001 shows a disk coating system of this kind.

Another approach for the transport is to draw the carriers in the vacuum chamber by magnets moved mechanically outside the chamber on atmosphere along the transport path. This avoids vacuum feed-throughs and allows increased accelerating forces on the carriers, but needs a complicated mechanical set-up of rotating magnetized double-helix rods or belts capped with magnets. Furthermore the precise positioning of the carriers becomes complicated. The controlling of the mechanics has to overcome the backlash and the hysteresis of the magnetic forces.

### SUMMARY OF THE INVENTION

The solution according to the invention is to use a linear synchronous motor, based on a hybrid layout of coils, magnets and Fe-yokes for the stator and the reluctance principle (without permanent magnets) for the driven carrier.

### BRIEF DESCRIPTION OF THE DRAWINGS

FIG. 1 shows a substrate carrier for a linear drive in vacuum;

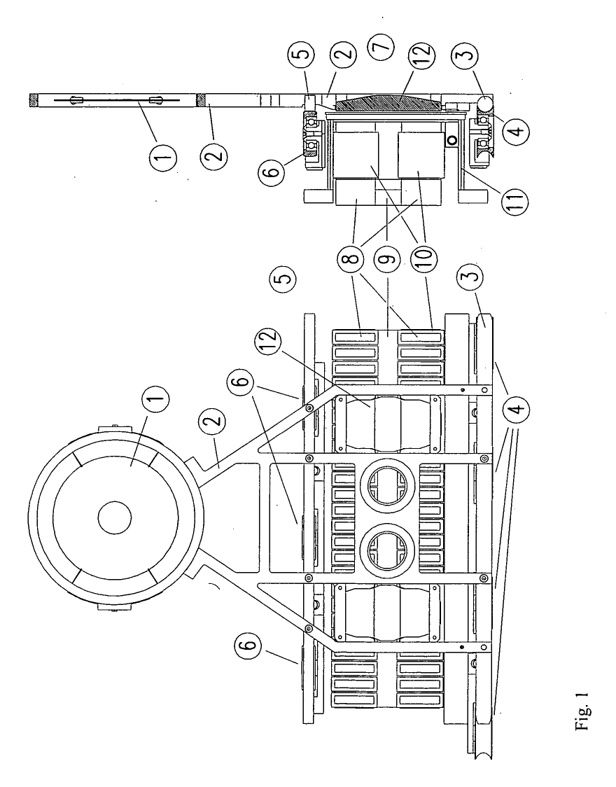

FIG. 2 shows a vacuum coating apparatus with two stacked lines/rows of processing stations connected by lift modules at both ends. The left lift module and the first process chamber is shown in opened condition; and

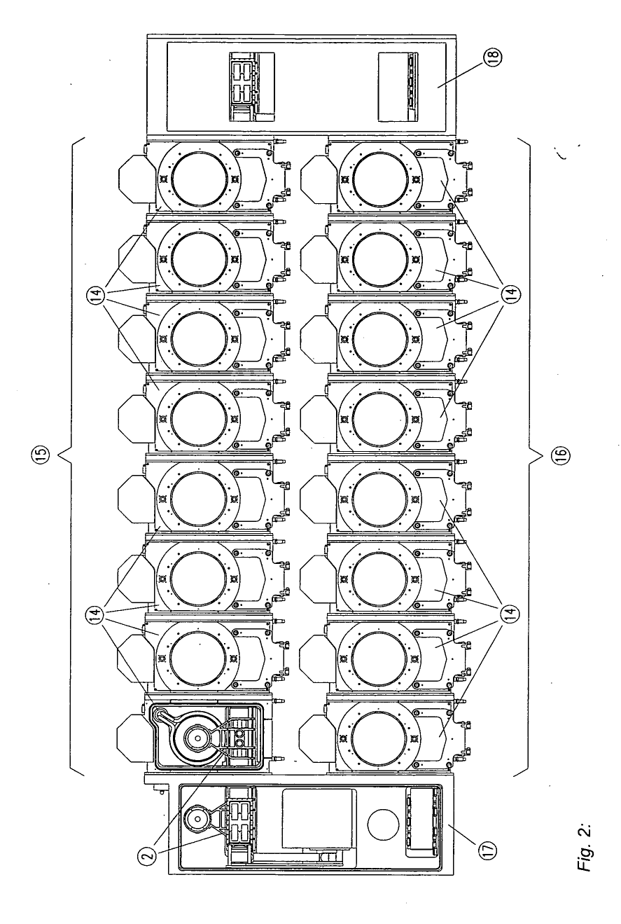

FIG. 3 shows a lift module for elevating a substrate carrier from one line up/down to the other.

### DETAILED DESCRIPTION

In a first, preferred embodiment the transport system relies on rails (3, 5) fixed to the carrier (2) and rollers (4, 6) mounted in the vacuum chamber (7), e.g. laterally at the side wall. The carrier is aligned in vertical orientation and, with only rails and no rollers on it, it provides a very slim cross-section. This allows narrow transfer slots between the process chamber for fast acting gate valves of less than 20 mm stroke. The attractive force of the linear motor presses the rails (3, 5) of the carrier on the rollers (4, 6). The lower row of rollers (3) in the chamber has a ‘gothic arc’ (concave) cross-section. The adjacent rail (4) of circular shape fit into the gothic arc and give the vertical positioning of the carriers. The upper row of rollers (5) have a slightly convex shape and the adjacent rails (6) are rectangular. This provides the exactly vertical orientation of the carriers.

In a further embodiment the carriers may be equipped with rollers interacting with fixedly mounted rails in the vacuum chamber. Design of rollers and rails may be similar and the holding and moving mechanism can be used as described above. In extended substrate treatment systems with few carriers only the number of vacuum capable bearings in the rollers can thus be reduced.

The stator part of the linear motor with Fe-yokes (8), magnets (9) and coils (10) is mounted at atmosphere in a stainless steel trough (11), placed in some Millimeter distance to the carrier (2) and providing the vacuum separation. In accordance with the embodiments above, the trough preferably is arranged at or forming part of the side wall of the process chamber. The trough's wall material of low electrical conductivity, like stainless steel, holds the eddy currents low for higher operation frequency and speed of the synchronous motor. The carrier (2) is equipped with pieces (12) of ferromagnetic material in a distance appropriate to the periodicity of the stator poles (8). The wandering field generated by the stator attracts the ferromagnetic parts of the carrier and provides the accelerating and de-accelerating forces. In the vicinity of the gate valves between the process modules exists a travel length without stator poles. To have at any position driving forces the carrier is equipped with two ferromagnetic parts in a distance larger than the length without stator poles along the traveling path.

The preferred embodiment described above has the following advantages:
High acceleration forces: Acceleration of up to 3 g and transport time of less than 0.25 sec between process positions is shown.
Fast and precise positioning is enabled by electronic control and electromagnetic forces, no mechanical moving parts exist in the driving unit, no feed-throughs must be placed into the vacuum chamber. The magnetic field on atmosphere is penetrating the nonmagnetic chamber walls generating forces inside the vacuum.
The driving apparatus allows for going without permanent magnets mounted on the carrier. This provides easy handling and cleaning of the carriers without attractive forces between them.
No carrier drop or substrates drop in case of power loss. The permanent magnets introduced in the stator of the linear drive hold the carriers in position without coil current. Furtheron synchronous transport of all carriers or and independent carrier transport in sub-groups of process modules can be easily accomplished. In consequence carrier can be positioned independently in each process module.

Principally the proposed solution could, in a further embodiment, be arranged at the bottom of the process chamber with rails/rollers arranged in a horizontal plane. However, in order to avoid tilting of the substrate carriers on the rails/rollers, the rails have to be arranged with a certain distance. The gate valves separating the process chamber have to allow enough space for this broader carrier.

The carriers perform a round trip in the vacuum apparatus and the load/unload of substrates from the clean room to the vacuum is at the end position of the apparatus in a single module or in adjacent modules. To move the substrate carriers from one linear line of process modules to the other a further vacuum transport mechanism is necessary. Existing solutions normally use mechanically driven sledges. This results in high mass and large number of moved parts and result in limited speed and the risk of particle generation.

In the solution according to the invention two lines (15, 16) of process modules (14), one stacked above the other, are connected at the ends by lift modules (17, 18). In the lift modules only the carrier (2), delivered by the linear drive described above, is taken out of its roller path of one line and then placed onto the roller path of the other line.

The vertical transport in the lift modules (17, 18) is driven by a rotational direct drive motor (19). This motor rotates a lever (20) that is connected to lift gripper box (21). A kinematics provides always the vertical orientation of the gripper box during the rotation. The gripper box (21) comprises magnet/iron yoke arrays (22) that give attractive forces on the ferromagnetic pieces (12) in the carrier and similar magnet/iron yoke arrays (23) that give a repulsive force against the poles (8) of the stator of the linear drive. The attractive and repulsive arrays (22, 23) comprise an assembly of magnets (24) and iron yokes (25).

The transfer of a carrier from one transport line to the other line starts when the carrier is brought to position by the linear drive. By rotation of the motor (19) the lift gripper box (21) is approaching the carrier. The attractive force of the magnet arrays (22) onto the ferromagnetic pieces (12) in the carrier is over-compensated by the repulsive force of the magnet array(s) (23). The current through the coils (10) adjacent to the approaching magnet array (23) can adjust this force. Rings of Viton (or of another elastomer) fixed to the lift gripper box are now settled smoothly into the appropriate deepening in the carrier. This provides a well-defined position of the carrier on the lift gripper without metallic contact. The carrier is released from the stator of the linear drive by applying an appropriate current on the coils (10) in next neighborhood to the ferromagnetic pieces (12). The carrier, fixed to the lift gripper by the magnetic forces of the arrays (22) is moved perpendicular to the plane of the rails (3, 5) out of the roller paths.

Alternatively a shunt plate can be approached from the backside of the linear motor opposite to the lift gripper. This shunt plate may consist of ferromagnetic yoke material (e.g. Fe). Thereby magnetic field lines are deviated from the linear motor into the plate and thereby the field attracting the carrier is weakened. In a further embodiment the shunt plate comprises yoke material and permanent magnets. This way even an overcompensation of the magnetic field of the linear motor and a net repulsive force between the linear motor and the carrier could be achieved in regions other than those covered by the ferromagnetic pieces (12); both enabling a very well controlled carrier release from the stator of the linear drive.

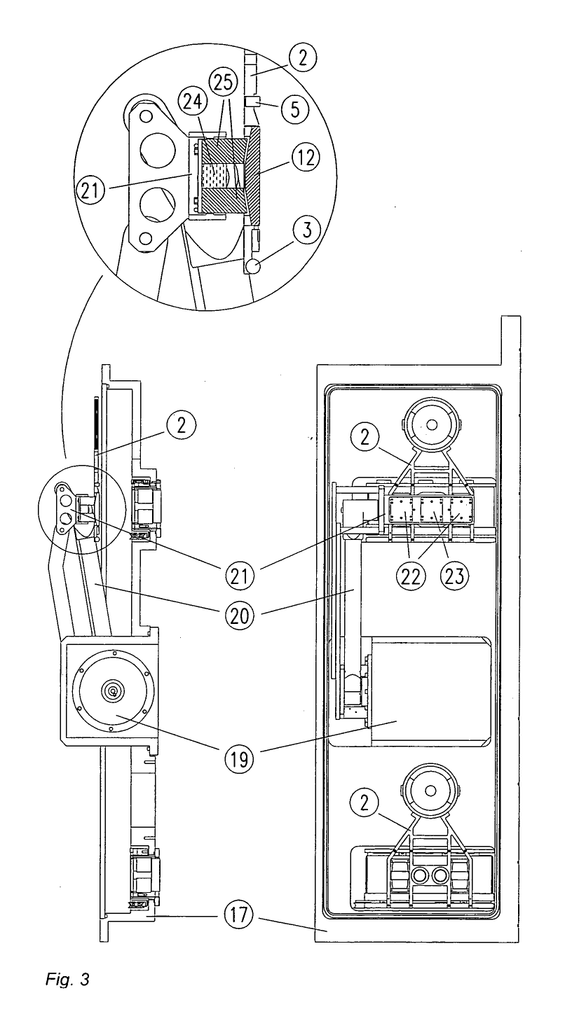

With respect to FIG. 3, a 180-degree turn of the motor (19) lifts the carrier to the other transport line. A soft approach to the rollers (4, 6) is provided by the appropriate current management for the coils (10) in the approached stator. The attractive force on the ferromagnetic pieces (12) is reduced and the repulsive force on the magnet arrays (23) is adjusted for a force on the lever (20) that is in sum slightly repulsive. Then the motor (19) can settle softly the carrier rails (3, 5) on the rollers (4, 6). For releasing the gripper (21) from the carrier (2) the attractive force on carrier towards the stator is increased by a reversed current in the coils (10) neighboring the ferromagnetic pieces (12). Supported by the repulsive force on the magnet arrays (23) the motor (19) can remove the gripper from the carrier. The carrier is ready to be transported by the linear motor in the next process station and the lift gripper is ready to take over the next carrier waiting in the other line. The magnetic forces of the magnet arrays (22 & 23) can be supported and adjusted by additional coils on the iron yokes (25).

Advantages of the lift module described above:
Low risk of particle generation—no metallic contact between carrier and gripper, smooth settling of carrier and gripper to the positions, only magnetic forces to hold the carrier.
Simple mechanics—for transport only 180 degree turn, no moved mechanics for gripping
Fast operation by low accelerated mass
Compatible with direct linear drive concept
No carrier drop in case of power break down—holding forces provided by permanent magnets

What is claimed:

1. A substrate processing system for the treatment of substrates in vacuum comprising:
a first linear assembly of process modules (14);
a second linear assembly of process modules, stacked above the first set of process modules (14);
at least one lift module (18) allowing for the transport from the first set to the second set;
a traveling path through the first and second set of process modules;
a linear synchronous motor arranged along said traveling path;
at least one substrate carrier (2) with rails (3, 5), said carrier in vertical orientation being movable along said traveling path
a transport system for said substrate carrier with a lower row of rollers (4) and an upper row of rollers (6) mounted in the process modules,
said rollers (4, 6) interacting with the rails (3, 5) of said substrate carrier (2) and attractive forces of said linear synchronous motor holding the carriers in vertical position.

2. A substrate processing system according to claim 1, wherein gate valves are arranged between process modules.

3. A substrate processing system according to claim 1, wherein the rollers (4, 6) are mounted in the vacuum chamber (7) at the side wall.

4. A substrate processing system according to claim 1, wherein the rollers of the lower row of rollers (3) has a ‘gothic arc’ cross section and the adjacent rail (4) has a circular shape.

5. A substrate processing system according to claim 1, wherein the rollers of the upper row of rollers (5) have a slightly convex shape and the adjacent rails (6) are rectangular.

6. A substrate processing system according to claim 1, wherein the stator part of the linear synchronous motor has a hybrid layout of Fe-yokes (8), magnets (9) and coils (10).

7. A substrate processing system according to claim 1, wherein the substrate carrier is equipped with at least two spaced apart pieces (12) of ferromagnetic material.

8. A substrate processing system according to claim 1, wherein the stator part of the linear synchronous motor is mounted at atmosphere in a stainless steel trough (11).

9. A substrate processing system according to claim 1, wherein said lift module comprises a rotational direct drive motor (19), a lever (2) and a lift gripper box (21).

10. A substrate processing system according to claim 9, wherein the lift gripper box comprises attractive and repulsive arrays (22, 23) with an assembly of magnets (24) and iron yokes (25).

11. A transport system for use in a vacuum processing system comprising:
at least one vacuum chamber with a linear synchronous motor arranged along a traveling path through said chamber,
a lower row of rollers (4) and a upper row of rollers (6) mounted at a side wall of said vacuum chamber,
at least one substrate carrier (2) with rails (3, 5), said carrier in vertical orientation being movable along said traveling path,
said rollers interacting with the rails of said substrate carrier and attractive forces of said linear synchronous motor holding the carrier in vertical position.

12. A method for manufacturing a magnetic hard disc in a substrate processing system according to claim one comprising the steps of:
introducing a substrate to be processed into said substrate processing system;
holding said substrate by means of a substrate carrier;
moving said carrier and substrate along a traveling path through at least one processing module;
processing said substrate in at least one process module;
unloading said substrate from said carrier after processing; and
withdrawing said substrate from said substrate processing system.
